(19) United States
(12) Patent Application Publication
(10) Pub. No.: US 2009/0008745 A1
(43) Pub. Date: Jan. 8, 2009

(54) Nitride Compound Semiconductor and Process for Producing the Same

(75) Inventors: Kenji Kasahara, Tsukuba (JP); Makoto Sasaki, Tsukuba (JP); Masaya Shimizu, Niihama (JP)

Correspondence Address: FITCH, EVEN, TABIN & FLANNERY, P. O. BOX 18415, WASHINGTON, DC, 20036, US

(73) Assignee: Sumitomo Chemical Company, Limited, Tokyo (JP)

(21) Appl. No.: 11/658,865

(22) PCT Filed: Jul. 28, 2005
(86) PCT No.: PCT/JP05/14270

§ 371 Date: Jan. 30, 2007

(30) Foreign Application Priority Data
Jul. 30, 2004 (JP) 2004-223439

(51) Int. Cl. H01L 29/06; H01L 21/205

(52) U.S. Cl. 257/615; 438/478; 257/E21.108; 257/E29.089

(57) ABSTRACT

A process for producing a nitride compound semiconductor represented by a general formula, InₓGa_{y}Al_{z}N (where x+y+Z=1, 0≦x≦1, 0≦y≦1, and 0≦z≦1), characterized in that a non-doped nitride compound semiconductor (A) represented by a general formula, InₐGa_{b}Al_{c}N (where a+b+c=1, 0≦a≦1, 0≦b≦1, and 0≦c≦1) of a thickness of 500 to 5000 Å is formed between a p-type contact layer and an n-type contact layer at a temperature within a range between 550 and 850° C.

### TECHNICAL FIELD

The present invention relates to a nitride compound semiconductor represented by a general formula, InₓGa_{y}Al_{z}N (where x+y+Z=1, 0≦x≦1, 0≦y≦1, and 0≦z≦1), and a process for producing the same.

### BACKGROUND ART

In recent years, a light emitting element using a nitride compound semiconductor represented by a general formula, InₓGa_{y}Al_{z}N (where x+y+Z=1, 0≦x≦1, 0≦y≦1, and 0≦z≦1) has been incorporated and commercialized as a light source for a blue, green or white light emitting device. In this type of light emitting element, a nitride compound semiconductor layer is formed on a substrate such as a sapphire substrate.

In the process of manufacturing a light emitting device wherein a light emitting element constituted as described above is incorporated, or in the situation of operating the light emitting device, if a large current flows instantaneously in the nitride compound semiconductor due to static electricity, a problem wherein the compound semiconductor is destroyed occurs.

In order to solve this problem, in a nitride compound semiconductor constituting a semiconductor light emitting element, a process wherein a p-type multilayer film is laminated on a light emitting layer consisting of a multi-quantum well, and a non-doped layer is formed between the p-type multilayer film and a p-type contact layer at a temperature of 1050° C. (e.g., refer to Patent Document 1); a process wherein an n-type multilayer film, a multi-quantum well and a p-type multilayer film are laminated (e.g., refer to Patent Document 2); and a processwherein an n-type layer having an electron concentration lower than an n-type contact layer is formed between a light emitting layer and the n-type contact layer at a temperature of 1150° C. (e.g., refer to Patent Document 3); and the like have been proposed.

[Patent Document 1] JP-A-2001-148507

[Patent Document 2] JP-A-2000-244072

[Patent Document 3] JP-A-9-92880

However, in the above-described process for forming a non-doped layer at a temperature of 1050° C., the process for laminating n-type multilayer film, a multi-quantum well and a p-type multilayer film, and the like, electrostatic breakdown resistance could not been satisfied; and in the process wherein an n-type layer having a low electron concentration is formed at a temperature of 1150° C., there was a problem wherein although the electrostatic withstand voltage in the forward direction could be improved, the improvement of the electrostatic withstand voltage in the backward direction was insufficient.

### DISCLOSURE OF THE INVENTION

An object of the present invention is to solve the above-described problems in conventional art, and to provide a nitride compound semiconductor that produces an element exhibiting a high electrostatic breakdown resistance, and a process for producing the same.

As a result of keen examinations to solve the above-described problems, the present inventors found that electrostatic withstand voltage was dramatically improved by forming a specific nitride semiconductor layer between a p-type contact layer and an n-type contact layer leading to the present invention.

Specifically, the present invention provides:

(1) a process for producing a nitride compound semiconductor represented by a general formula, InₓGa_{y}Al_{z}N (where x+y+Z=, 0≦x≦1, 0≦y≦1, and 0≦z≦1), characterized in that a non-doped nitride compound semiconductor (A) represented by a general formula, InₐGa_{b}Al_{c}N (where a+b+c=1, 0≦a≦1, 0≦b≦1, and 0≦c≦1) of a thickness of 50 to 500 nm is formed between a p-type contact layer and an n-type contact layer at a temperature within a range between 550 and 850° C.;

(2) the process according to the above-described (1), wherein a non-doped nitride compound semiconductor (B) represented by a general formula, In_{d}GaₑAl_{f}N (where d+e+f=1, 0≦d≦1, 0≦e≦1, and 0≦f≦1) of a thickness of 20 to 600 nm is formed between the nitride compound semiconductor (A) and the n-type contact layer at a temperature within a range between 900 and 1200° C.; and

(3) a nitride compound semiconductor obtained by a process according to the above-described (1) or (2).

The present invention also provides a light emitting element having the above nitride compound semiconductor.

Hereupon, the word “non-doped” in the present invention means that impurities are not intentionally added.

### BRIEF DESCRIPTION OF THE DRAWINGS

FIG. 1 is a sectional view showing an example of nitride compound semiconductors produced according to a producing method of the present invention; and

FIG. 2 is a circuit diagram for testing the resistance to the electrostatic discharge of a light emitting element.

FIG. 3 shows the structure of the light emitting element of the present invention.

### BEST MODE FOR CARRYING OUT THE INVENTION

An example of the embodiment of the present invention will be described below referring to the drawings.

The nitride compound semiconductor to be the subject of the present invention is a compound semiconductor represented by a general formula, InₓGa_{y}Al_{z}N (where x+y+Z=1, 0≦x≦1, 0≦y≦1, and 0≦z≦1).

As a substrate for growing the nitride compound semiconductor, a nitride compound semiconductor substrate, a sapphire substrate, an SiC substrate, an Si substrate, a ZrB₂ substrate and the like can be preferably used. Here, if a nitride compound semiconductor is grown directly on the above-described substrates other than the nitride compound semiconductor substrate, a sufficiently high-quality crystal may not be produced because of lattice mismatch. In such a case, it has been well known that a high-quality crystal can be obtained by a two-stage growing process wherein a layer of GaN, AlN, SiC or the like is first grown on a substrate as a buffer layer, and then, a nitride compound semiconductor is further grown.

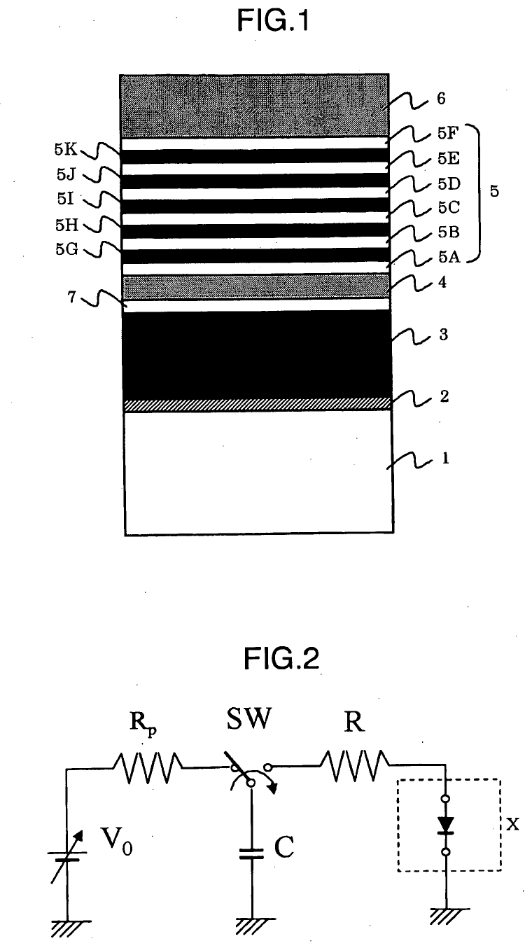

FIG. 1 is a sectional view showing a frame format of the structure of nitride compound semiconductor to which the present invention is applied.

Although various known processes are included in the processes for manufacturing the nitride compound semiconductor, the use of a metal organic vapor phase epitaxial growth process (MOVPE process) is preferred. Hereafter, a manufacturing process using the MOVPE process will be described.

A GaN buffer layer (low-temperature buffer layer) 2 is formed on a sapphire substrate 1, and an n-type contact layer 3 is formed on the GaN buffer layer. The thickness of the GaN buffer layer 2 is preferably 10 to 100 nm. As the buffer layer, the mixed crystal of AlN and GaN represented by a general formula, Ga_{y}Al_{1-y}N (where 0<y<1) can also be used.

It is preferable not to elevate the operating voltage of a light emitting element, the n-type carrier concentration in the n-type contact layer 3 is 1×10¹⁸ cm⁻³ or higher and 1×10²¹ cm⁻³ or lower. Such an n-type contact layer can be easily obtained by a well-known process wherein an adequate quantity of an n-type dopant gas or an organic metal material is added when the crystal of InₓGa_{y}Al_{z}N (where x+y+Z=1, 0≦x≦1, 0≦y≦1, and 0≦z≦1) is grown at a temperature within the range between 900 and 1100° C. As the material of the n-type dopant, silane, disilane, german, tetramethyl germanium or the like is preferred. The n-type carrier concentration exceeding 1×10²¹ cm⁻³ is not preferable because crystallizing properties becomes poor, and the characteristics of the light emitting element are adversely affected.

In addition, if the mixing ratio of In and Al in the mixed crystal is high, the quality of the crystal lowers and the carrier concentration elevates especially at low temperatures; therefore, the In composition is preferably 5% or less, and more preferably 1% or less. The Al composition is preferably 5% or less, and more preferably 1% or less. Most preferably, the n-type contact layer 3 is composed of GaN.

On the above-described n-type contact layer 3, a non-doped nitride compound semiconductor 4 represented by a general formula, InₐGa_{b}Al_{c}N (where a+b+c=1, 0≦a≦1, 0≦b≦1, and 0≦c≦1) is formed. The semiconductor layer 4 is grown at a temperature within the range between 550 and 850° C., preferably within the range between 700 and 800° C. For example, the growing temperature is set at 775° C., ammonia gas is used as a group V material, and triethyl gallium is used as a group III material to grow a crystal. At this time, it is important that no n-type dopant gas and p-type dopant gas are intentionally added to produce non-doping conditions. The n-type carrier concentration of the nitride compound semiconductor layer 4 formed under these crystal growing conditions can be 1×10¹⁷ to 1×10¹⁸ cm⁻³.

In the nitride compound semiconductor 4, since the crystal quality is lowered and the carrier concentration is elevated if the mixed crystal ratio of In and Al is high, especially at low temperatures, the In composition is preferably 5% or less, and more preferably 1% or less. The Al composition is preferably 5% or less, and more preferably 1% or less. The nitride compound semiconductor 4 is most preferably GaN.

If the film thickness of the nitride compound semiconductor layer 4 is excessively thin, the effect to improve the electrostatic withstand voltage tends to lower; and if it is excessively thick, element characteristics may be adversely affected, such as increase in leakage current when the light emitting element is operated. Therefore, the film thickness of the nitride compound semiconductor layer 4 is normally within the range between 50 and 500 nm, and preferably within the range between 70 and 250 nm.

Although the nitride compound semiconductor layer 4 works as a barrier layer that contacts the lower surface of the well layer, which is a light emitting layer as described below; however, it can be formed between the n-type contact layer and the barrier layer. It can also work as a barrier layer that contacts the upper surface of the well layer, or can be formed between the p-type contact layer and the barrier layer.

Further, a non-doped nitride compound semiconductor layer 7 represented by a general formula, In_{d}GaₑAl_{f}N (where d+e+f=1, 0≦d≦1, 0≦e≦1, and 0≦f≦1) can be formed between the n-type contact layer 3 and the nitride compound semiconductor layer 4. This is preferable because better electrostatic withstand voltage characteristics, good LED light emitting characteristics and electrical characteristics can be obtained. The semiconductor layer 7 is grown at a temperature within the range between 900 and 1200° C., preferably at a temperature within the range between 1000 and 1150° C. For example, a crystal is grown at a growing temperature of 1100° C. using ammonia gas as the group V material and triethyl gallium as the group III material. At this time, the n-type dopant gas and the p-type dopant gas are not intentionally mixed to make non-doping conditions. The n-type carrier concentration of the semiconductor layer 7 formed under these crystal growing conditions can be lower than 5×10¹⁶ cm⁻³, preferably 1×10¹⁶ cm⁻³ or lower.

However, if such a low-carrier-concentration layer is excessively thick, it becomes the serial resistor component of the light emitting element; therefore, the film thickness of the semiconductor layer 7 is preferably 600 nm or less, more preferably 10 to 300 nm, and further preferably 50 to 300 nm.

In the nitride compound semiconductor 7, if the mixed crystal ratio of In and Al is high, the crystal quality lowers especially at low temperatures, and the carrier concentration elevated; therefore, the In composition is preferably 5% or lower, and more preferably 1% or lower. The al composition is preferably 5% or lower, and more preferably 1% or lower. Most preferably, the n-type contact layer 7 is composed of GaN.

Next, a light emitting layer 5 is formed on the above-described nitride compound semiconductor layer 4. The light emitting layer 5 shown in FIG. 1 is a multi-quantum well structure consisting of GaN layers 5A to 5E, which are barrier layers, and In_{g}GaₕN layers (where g+h=1, 0<g<1, 0<h<1) 5F to 5J, which are well layers. Although the well layers consist of five layers, it is enough if there is at least one well layer. Here, the film thickness and the mixed crystal ratio of GaN layers 5A to 5E and In_{g}GaₕN layers 5F to 5J can be appropriately determined according to the characteristics of the target light emitting element. For example, a blue light emitting element with an emission wavelength of about 470 nm is the target, the thickness of the GaN layer is 3 to 30 nm, the thickness of the In_{g}GaₕN layer can be 1 to 5 nm, and the average In composition can be about 5 to 40%.

A p-type contact layer 6 is formed on the above-described light emitting layer 5. In the p-type contact layer 6, in order not to elevate the operating voltage of the light emitting element, the p-type carrier concentration is preferably 5×10¹⁵ cm⁻³ or higher, and more preferably 1×10¹⁶ to 5×10¹⁹ cm⁻³. Such a p-type contact layer can be easily obtained by a well known process wherein after mixing an appropriate quantity of material gas for the dopant to grow the crystal, heat treatment is performed when the InₐGa_{b}Al_{c}N (where a+b+c=1, 0≦a≦1, 0≦b≦1, and 0≦c≦1) crystal is grown at a growing temperature of 800° C. to 1100° C.

In the p-type contact layer 6, if the mixed crystal ratio of Al is high, the contact resistance tends to elevate, the Al composition is normally 5% or lower, and preferably 1% or lower. The p-type contact layer 6 is more preferably InGaN or GaN, and most preferably GaN.

When each layer as described above is grown using the MOVPE process, the following materials can be appropriately selected and used.

The examples of group III gallium materials include trialkyl gallium represented by a general formula, R₁R₂R₃Ga (where R₁, R₂ and R₃ denote lower alkyl groups), such as trimethyl gallium (TMG) and triethyl gallium (TEG).

Aluminum materials include trialkyl aluminum represented by a general formula, R₁R₂R₃Al (where R₁, R₂ and R₃ denote lower alkyl groups), such as trimethyl aluminum (TMA), triethyl aluminum (TEA) and triisobutyl aluminum.

Indium materials include trialkyl indium represented by a general formula, R₁R₂R₃In (where R₁, R₂ and R₃ denote lower alkyl groups), such as trimethyl indium (TMI) and triethyl indium; trialkyl indium whose one to three alkyl groups are replaced by halogen atoms, such as diethyl indium chloride; and halogenated indium represented by a general formula, InX (where X is a halogen atom), such as indium chloride.

The examples of group V materials include ammonia, hydrazine, methyl hydrazine, 1,1-dimethyl hydrazine, 1,2-dimethyl hydrazine, t-butylamine and ethylenediamine. These materials can be used alone or in optional combination. Of these materials, ammonia and hydrazine are preferable because they contain no carbon atoms in the molecules, and have little effect of carbon contamination to the semiconductor.

The examples of p-type dopants include Mg, Zn, Cd, Ca, Be and the like. Among these, Mg and Ca are preferably used. As the material of Mg, which is a p-type dopant, for example, bis(cyclopentadienyl)magnesium ((C₅H₅)₂Mg), bis(methylcyclopentadienyl)magnesium ((C₅H₄CH₃)₂Mg), bis(ethylcyclopentadienyl)magnesium ((C₅H₄C₂H₅)₂Mg) or the like can be used. As the material of Ca, bis(cyclopentadienyl)calcium ((C₅H₅)₂Ca) and the derivatives thereof, for example, bis(methylcyclopentadienyl)calcium ((C₅H₄CH₃)₂Ca), bis(ethylcyclopentadienyl)calcium ((C₅H₄C₂H₅)₂Ca) or bis(perfluorocyclopentadienyl) calcium ((C₅F₅)₂Ca), di-1-naphthalenyl calcium and the derivatives thereof, or calcium acetylide and the derivatives thereof, for example, bis(4,4-difluoro-3-butene-1-inyl)calcium or bis(phenylethynyl)calcium can be used. These materials can be used alone or in combination of two or more.

Although the case wherein an MOVPE process is used is described in this embodiment, the present invention is not limited thereto, but other well known processes for growing the crystal of a III-V group compound semiconductor, such as molecular beam epitaxy, can also be used.

The light emitting element of the present invention is characterized by having a nitride compound semiconductor obtained by the above-described production process.

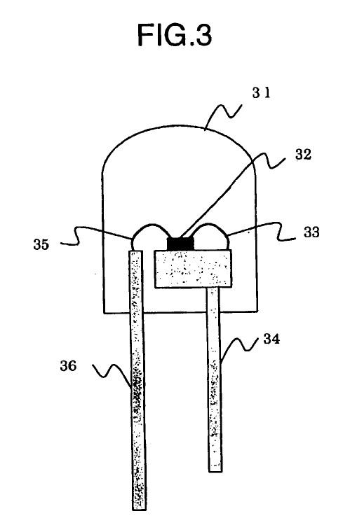

For example, FIG. 3 is a sectional view showing an example of the light emitting element having a nitride compound semiconductor according to the present invention. By the conventional method, on the nitride compound semiconductor, a p-electrode is formed on a p-type contact layer and an n-electrode on an n-type contact layer, followed by chip process. The nitride compound semiconductor after the chip process is fixed onto a mount integrally formed at the inside end of a first lead frame 34. A second lead frame 36 is provided to become approximately parallel to the first lead frame 34. The n-electrode of the light emitting element 32 is electrically connected to the mount portion through a first connecting conductor 33, and the p-electrode is electrically connected to the second lead frame 36 through a second connecting conductor 35. The inside ends of the first lead frame 34 and the second lead frame 36 are sealed with a transparent thermosetting resin 31. Accordingly, light emission can be obtained from the light emitting element by applying a voltage between the first lead frame and the second lead frame. The light from the light emitting element is emitted outside through the transparent thermosetting resin 31.

### EXAMPLES

The examples of the present invention will be described below; however, the present invention is not limited thereto.

### Example 1

As a substrate, sapphire whose C surface was mirror polished was used. The process for growing a crystal was conducted by an MOVPE process, and a two-stage growth process using GaN grown at a low temperature was used as a buffer layer. The pressure in the growing furnace was set to 1 atmosphere, the substrate temperature was set at 550° C., hydrogen was used as the carrier gas, and TMG and ammonia was supplied to grow a GaN buffer layer of a thickness of about 50 nm.

Next, after elevating the substrate temperature to 1120° C., hydrogen carrier gas, TMG, silane and ammonia were supplied to grow an Si-doped n-type GaN layer of a thickness of about 4 μm, and supply of only silane was stopped to grow a non-doped GaN layer of a thickness of 300 nm.

Then, the substrate temperature was set at 780° C., the pressure in the growing furnace was set to 50 kPa, nitrogen was used as the carrier gas, and 610 sccm and 40 slm of TEG and ammonia, respectively, were supplied to grow the non-doped GaN layer of a thickness of 100 nm as the nitride compound semiconductor layer A of the present invention.

Then, 610 sccm, 1160 sccm and 40 slm of TEG, TMI and ammonia, respectively, were supplied to grow an In_{0.12}Ga_{0.88}N layer of a thickness of 3 nm. Then, 610 sccm and 40 slm of TEG and ammonia, respectively were supplied to grow a non-doped GaN layer of a thickness of 15 nm.

The operations to grow the In_{0.12}Ga_{0.88}N well layer (3 nm) and the non-doped GaN barrier layer (15 nm) were repeated further four times; however, only the film thickness of the uppermost non-doped GaN barrier layer was made 18 nm.

Then, after elevating the substrate temperature to 940° C., 600 sccm, 200 sccm, 3000 sccm and 40 slm of TEG, TMA, bis(cyclopentadienyl)magnesium (hereafter abbreviated as EtCp2Mg) and ammonia, respectively, were supplied to grow a Mg-doped Al_{0.1}Ga_{0.9}N layer (protection layer) of a thickness of 30 nm. Furthermore, after elevating the substrate temperature to 1000° C., EtCp2Mg and ammonia were supplied to grow a Mg-doped p-type GaN layer of a thickness of 150 nm as a p-layer.

The nitride compound semiconductor sample thus made is taken out from the reaction furnace, and then subject to annealing of 700° C. for 20 minutes to convert a Mg-doped GaN layer (top layer), to a low-resistive p-type layer.

Electrodes were formed by a normal process on thus obtained sample to form a light emitting diode (hereafter abbreviated as LED). A Ni—Au alloy was used as a p-electrode, and Al was used as an n-electrode. When a current of 20 mA was flowed in this LED in the forward direction, the LED exhibited clear blue light emitting. The resistance of the LED to electrostatic discharge was tested as follows:

FIG. 2 is a circuit diagram of the circuit for testing the resistance of the LED to electrostatic discharge. Here, Vo denotes a variable direct current power source, Rp and R denote resistors, C denotes a capacitor, and Sw denotes a changing-over switch. As the test, the following machine model test was conducted. The machine model test is a model for discharging static electricity to an LED from an electrostatically charged apparatus or jig under conditions of R=0Ω and C=200 pF. After setting the voltage of the variable direct current power source Vo in FIG. 2 to a certain value, and switching the changing-over switch Sw as shown by a solid line to charge the capacitor C through the resistor Rp, the changing-over switch Sw is switched as a dotted line to discharge to the LED. After the tests were repeated three times, the voltage-current characteristics of the light emitting element were evaluated. Change in the voltage-current characteristics of the light emitting element enables the judgment whether the element was destroyed or not. Hereafter, the Vo value when 50% of the total tested elements were destroyed was made the electrostatic withstand voltage value. The electrostatic withstand voltage in this example was 417 V.

### Example 2

An LED was fabricated in accordance with Example 1 except that the film thickness of the nitride semiconductor layer A was 200 nm. When a current of 20 mA was flowed in this LED in the forward direction, the LED exhibited clear blue light emitting. The electrostatic withstand voltage was 417 V.

### Example 3

An LED was fabricated in accordance with Example 1 except that the film thickness of the nitride semiconductor layer B was 150 nm. When a current of 20 mA was flowed in this LED in the forward direction, the LED exhibited clear blue light emitting. The electrostatic withstand voltage was 200 V.

### Comparative Example 1

An LED was fabricated in accordance with Example 1 except that the substrate temperature when the nitride semiconductor layer A was grown was 889° C. When a current of 20 mA was flowed in this LED in the forward direction, the LED exhibited clear blue light emitting. The electrostatic withstand voltage was 75 V.

### Comparative Example 2

An LED was fabricated in accordance with Example 1 except that the film thickness of the nitride semiconductor layer A was 15 nm. When a current of 20 mA was flowed in this LED in the forward direction, the LED exhibited clear blue light emitting. The electrostatic withstand voltage was 60 V.

### Comparative Example 3

An LED was fabricated in accordance with Example 1 except that the substrate temperature when the nitride semiconductor layer A was grown was 1124° C., the film thickness was 300 nm. When a current of 20 mA was flowed in this LED in the forward direction, the LED exhibited clear blue light emitting. The electrostatic withstand voltage was 88 V.

Table 1 shows the growing conditions and electrostatic withstand voltage of nitride semiconductor layers A.

The carrier concentration of the nitride semiconductor layer A is measured as follows: A low temperature buffer layer is grown on a sapphire substrate, on which low temperature buffer layer a GaN ground layer that is previously known to have a carrier concentration of 1×10¹⁶ cm⁻³ or less is grown in a thickness of about 3000 nm, on which the nitride semiconductor layer A of interest is grown in a thickness of about 200 nm. The thus obtained sample is subjected to hole measurement method to obtain the carrier concentration of the nitride semiconductor layer A.

In blue-light emitting diodes in Comparative Examples 1 to 3, the electrostatic withstand voltages were lower than 100 V.

On the other hand, in the case of Examples 1 and 2, the electrostatic withstand voltage was 417 volts, and in the case of Example 3, it was 200 V. In other words, it was confirmed that in the LEDs fabricated by the production process of the present invention, withstand voltage to electrostatic destruction is remarkably improved, specifically it is improved by about 300 V or more in Examples 1 and 2.

TABLE 1

| | Film | Growth | Carrier | Film | Growth | |
|---|---|---|---|---|---|---|
| | thickness of | temperature | concentration | thickness | temperature | |
| | nitride | of nitride | of nitride | of nitride | of nitride | Electrostatic |
| | semiconductor | semiconductor | semiconductor | semiconductor | semiconductor | withstand |
| | layer A | layer A | layer A | layer B | layer B | voltage |
| Example | (nm) | (° C.) | (cm⁻³) | (nm) | (° C.) | (V) |
| Example 1 | 100 | 780 | 6 × 10¹⁷ | 300 | 1120 | 417 |
| Example 2 | 200 | 780 | 6 × 10¹⁷ | 300 | 1120 | 417 |
| Example 3 | 100 | 780 | 6 × 10¹⁷ | 150 | 1120 | 200 |
| Comparative | 100 | 889 | 2 × 10¹⁷ | 300 | 1120 | 75 |
| Example 1 | | | | | | |
| Comparative | 15 | 780 | 6 × 10¹⁷ | 300 | 1120 | 60 |
| Example 2 | | | | | | |
| Comparative | 300 | 1124 | <1 × 10¹⁶ | 300 | 1120 | 88 |
| Example 3 | | | | | | |

In the same manner as in Example 1 except that the growth temperature and thickness of nitride semiconductor layers A and B were changed as shown in Table 2 below, the nitride compound semiconductors excellent in electrostatic withstand voltage were obtained.

TABLE 2

| | | Growth | | Growth |
|---|---|---|---|---|
| | Thickness of | temperature | Thickness of | temperature |
| | nitride | of nitride | nitride | of nitride |
| | semiconductor | semiconductor | semiconductor | semiconductor |
| | layer A | layer A | layer B | layer B |
| No. | (nm) | (° C.) | (nm) | (° C.) |
| 1 | 60 | 780 | 300 | 1100 |
| 2 | 300 | 780 | 300 | 1100 |
| 3 | 100 | 780 | 50 | 1100 |
| 4 | 100 | 780 | 500 | 1100 |
| 5 | 200 | 780 | 50 | 1100 |
| 6 | 200 | 780 | 500 | 1100 |
| 7 | 60 | 680 | 300 | 1100 |
| 8 | 100 | 680 | 300 | 1100 |
| 9 | 200 | 680 | 300 | 1100 |
| 10 | 150 | 780 | 50 | 950 |
| 11 | 150 | 780 | 500 | 950 |

### INDUSTRIAL APPLICABILITY

According to the present invention, the electrostatic destruction of a nitride compound semiconductor can be prevented even if abnormally high voltage and large current pulse caused by static electricity is impressed to the nitride compound semiconductor.

1. A process for producing a nitride compound semiconductor represented by a general formula, InₓGa_{y}Al_{z}N (wherein x+y+z=1, 0≦x≦1, 0≦y≦1, and 0≦z≦1, characterized in that a non-doped nitride compound semiconductor (A) represented by a general formula, InₐGa_{b}Al_{c}N (wherein a+b+c=1, 0≦a≦1, 0≦b≦1, and 0≦c≦1 and having a thickness of 500 to 5000 Å is formed between a p-type contact layer and an n-type contact layer at a temperature within a range between 550 and 850° C.

2. The process according to claim 1, wherein a non-doped nitride compound semiconductor (B) represented by a general formula, In_{d}Ga_{c}Al_{f}N wherein d+e+f=1, 0≦d≦1, 0≦e≦1, and 0≦f≦1 and having a thickness of 200 to 6000 Å is formed between said nitride compound semiconductor (A) and said n-type contact layer at a temperature within a range between 900 and 1200° C.

3. A nitride compound semiconductor obtained by a process according to claim 1.

4. A nitride compound semiconductor obtained by a process according to claim 2.
